(19) United States
(12) Patent Application Publication
(10) Pub. No.: US 2016/0064060 A1
(43) Pub. Date: Mar. 3, 2016

(54) METHOD OF FORMING A MAGNETIC DOMAIN WALL IN A NANOWIRE

(71) Applicant: Nanyang Technological University, Singapore (SG)

(72) Inventors: Chinkhanlun GUITE, Singapore (SG); Inn Seng KERK, Singapore (SG); Chandra Sekhar MURAPAKA, Singapore (SG); Wen Siang LEW, Singapore (SG)

(21) Appl. No.: 14/843,918

(22) Filed: Sep. 2, 2015

(30) Foreign Application Priority Data
Sep. 2, 2014 (SG) 10201405402X

(51) Int. Cl. G11C 11/16

(52) U.S. Cl. CPC G11C 11/1675; G11C 11/161

(57) ABSTRACT

A method of forming a domain wall in a nanowire, the method comprising the steps of: a) providing a conductive strip orthogonally to a nanowire adjacent a free end of the nanowire, the nanowire having an original magnetization direction; b) pulsing a current through the conductive strip to generate an Oersted field having a direction opposite to the original magnetization direction such that magnetization direction of a portion of the nanowire transversed by the conductive strip becomes opposite to the original magnetization direction, the domain wall being generated in the nanowire at a location defined between the portion of the nanowire transversed by the conductive strip and a second end of the nanowire, wherein no external magnetic field is provided during formation of the domain wall.

### CROSS-REFERENCE TO RELATED APPLICATIONS

This application claims priority to Singapore Application No. SG 10201405402X filed with the Intellectual Property Office of Singapore on Sep. 2, 2014 and entitled “METHOD OF FORMING A MAGNETIC DOMAIN WALL IN A NANOWIRE,” which is incorporated herein by reference in its entirety for all purposes.

### FIELD OF THE INVENTION

This invention relates to a method of forming a magnetic domain wall in a nanowire, and particularly, in a nanowire configured for data storage.

### BACKGROUND OF THE INVENTION

In racetrack memory [1] or domain wall memory, magnetic domain walls (DW) separate data bits in ferromagnetic nanowires (NW). Domain wall memory has the potential to change the known world of non-volatile memory because it has a possibility of achieving ultra-high areal density of memory with corresponding lower cost. In DW memory, the data bits along a nanowire are separated by DWs, which means multiple DWs have to exist together in a single nanowire. Motion of DWs through networks of ferromagnetic nanowires by current allows the data to be read or manipulated.

For device applications, a first step is to generate stable DWs for data writing in ferromagnetic nanowires. The DW generation or formation dictates two vital parameters such as speed of the device and its overall power consumption. One of the challenges in realizing such magnetic DW-based devices is the stochastic nature of domain wall injection or formation using localized Oersted field. The application of localized Oersted field that is antiparallel to the direction of magnetization of the nanowire creates two DWs along the nanowire, which are well known as head-to-head (HH) and tail-to-tail (TT) DWs that act as free magnetic monopoles having charges of opposite polarities.

The localized Oersted field is typically applied by providing a transverse conductive strip across the length of the nanowire and pulsing a current through the conductive strip. Depending on the direction of current application, the Oersted field is either parallel (i.e. in the same direction) or anti-parallel (i.e. in an opposite direction) to the magnetization direction of the nanowire. When the direction of the Oersted field is opposite to the nanowire magnetization, it flips the spins in the nanowire by 180 degrees (anti-parallel to the nanowire magnetization) where the conductive strip is overlapped to create two DWs in the nanowire on both sides of the conductive strip, i.e., alongside the edges of the conductive strip.

The two DWs (HH and TT) tend to attract each other due to their magnetostatic charge. This causes the two DWs to collide with each other leading to mutual annihilation or formation of a bound state. Mutual annihilation makes the DW injection or formation stochastic. In cases where the DWs form a bound state, it becomes difficult to drive them along the nanowire using current because they are formed underneath the conductive strip.

To overcome such problems, artificial notches formed on the nanowire and/or an external global magnetic field is applied to separate and prevent the said mutual attraction [2, 3]. Alternatively or in addition, multiple (100) pulses [4] are applied. However, forming artificial notches on the nanowire and/or applying multiple pulses increases production time and cost. The global magnetic field negates or counteracts the magnetostatic interaction between the DWs generated and drives them apart. It results in annihilation of one DW at one end of the nanowire (−x direction) and driving the other DW out of the conductive strip towards a second end of the nanowire (+x direction). However, the external magnetic field is not suitable for manipulating multiple DWs. Two consecutive DWs respond differently, altering the data bit widths, which may deteriorate the device performance. Furthermore, generation of a global external magnetic field may distract the data by moving other DWs within the nanowire. In addition, on-chip generation of global magnetic field is not energy efficient, and also imposes scalability issues for device application.

### SUMMARY OF INVENTION

The invention exploits the edge field at an end of the nanowire for deterministic generation without the need for an external global magnetic field to negate the magnetostatic interaction to stabilize the DWs, eliminating the requirement for multiple pulses [4]. This also eliminates the need for providing artificial notches in the nanowire, making the device simple and compact. The method provides a deterministic generation of a single domain wall (DW) in a magnetic nanowire by means of a local Oersted field from a current-carrying conductive strip.

By exploiting the natural edge field of the nanowire, one of the two DWs generated close to the edge or free end of the nanowire is annihilated immediately (in the picosecond range) right after generation. A single DW is left in the nanowire, which is free from any mutual magnetostatic interaction. Furthermore, using the present method, generation of a single DW is relatively faster with lower threshold current density as compared to injection or formation of two DWs. The absence of external magnetic field makes the device simple, compact and energy efficient.

A method of forming a domain wall in a nanowire, the method comprising the steps of: a) providing a conductive strip orthogonally to a nanowire adjacent a free end of the nanowire, the nanowire having an original magnetization direction; b) pulsing a current through the conductive strip to generate an Oersted field having a direction opposite to the original magnetization direction such that magnetization direction of a portion of the nanowire transversed by the conductive strip becomes opposite to the original magnetization direction, the domain wall being generated in the nanowire at a location defined between the portion of the nanowire transversed by the conductive strip and a second end of the nanowire, wherein no external magnetic field is provided during formation of the domain wall.

In step a), a first edge of the conductive strip may be at a distance from the free end of the nanowire that is sufficient for an edge field at the free end of the nanowire to prevent formation of a further domain wall in the nanowire adjacent the free end of the nanowire.

A width of the nanowire may be not less than 200 nm.

The distance may range from 0 nm to 500 nm.

The distance may be reduced when the width of the nanowire is reduced. The current may have a current density of at least 1.1×10¹² A/m².

The current may have a pulse width of 10 ns.

### BRIEF DESCRIPTION OF FIGURES

In order that the invention may be fully understood and readily put into practical effect there shall now be described by way of non-limitative example only exemplary embodiments of the present invention, the description being with reference to the accompanying illustrative drawings.

FIG. 1 is a schematic illustration of an exemplary set-up for a method of forming domain wall in a nanowire according to the present invention.

FIG. 2(a) shows simulated magnetization configurations of the nanowire of FIG. 1 at various stages (from 400 ps to 2000 ps) during current pulse injection.

FIG. 2(b) is a graph of correlation between single DW stabilization time as a function of a distance d between a transverse conductive strip and a free end of the nanowire.

FIG. 2(c) is a graph of correlation between minimum current density required for single DW generation or formation and the distance d.

FIG. 3(a) is a schematic illustration of a device circuit for single DW injection or formation in the nanowire with an inset of a scanning electron microscopy image showing a transverse conductive strip across the nanowire.

FIG. 3(b) is a magnetoresistance plot during DW injection or formation into the nanowire (Inset shows the magnetic force microscopy image of the single domain wall injected).

FIG. 3(c) is a probability plot of DW injection or formation for various current densities as a function of pulse duration

FIG. 4 is a flow chart of the method of the present invention.

FIG. 5 is a graph of threshold distance d for successful DW injection as a function of the nanowire width.

FIG. 6 is a graph of critical current density for DW injection as a function of width of the nanowire.

FIG. 7 is an illustration of possible different shapes of the free end of the nanowire.

### DETAILED DESCRIPTION

Exemplary embodiments of the method 100 of forming a magnetic domain wall 90 in a nanowire 10 will be described below with reference to FIGS. 1 to 7, in which the same reference numerals are used to denote the same or similar parts.

In the method 100, a transverse conductive stripe line or conductive strip 20 for Oersted field generation is placed as a second layer on top of a nanowire 10, i.e., the conductive strip 20 is provided orthogonally to or across the longitudinal axis (x) of the nanowire 10 adjacent a free end 11 of the nanowire 10 (102), as shown in FIG. 1. In a preferred embodiment, the nanowire 10 is made of Permalloy (NiFe). Alternatively, any in-plane magnetisable material may be used for the nanowire 10. The transverse conductive strip 20 is preferably made of gold (Au). Alternatively, any low resistance non-magnetic metallic material can be used as the conductive strip 20.

In experiments conducted to understand the effect of edge stray field of the nanowire 10, the nanowire 10 used was 4 μm long, 300 nm wide and 10 nm thick while the conductive strip 20 was 1 μm wide and 30 nm thick.

In the method 100, pulse current 28 is applied through the Au conductive strip 20 to generate the local Oersted field 30 opposite to the magnetization direction 40 of the NiFe nanowire 10 (104). The local Oersted field 30 switches the direction of magnetization 50 in the nanowire 10 below the transverse conductive strip 20, i.e., in a portion 60 of the nanowire 10 that is transversed by the conductive strip 20, so that magnetization direction 50 in the portion 60 of the nanowire 10 is opposite to the original magnetization direction 40 of the nanowire 10. The opposite magnetization direction 50 in the portion 60 of the nanowire 10 induces DWs in the nanowire 10 on the two sides 21, 22 of the conductive strip 20. As the conductive strip 20 is close to the left edge or free end 11 of the nanowire 10, the DW (not shown) generated in the nanowire 10 at the left or first edge 21 of the conductive strip 20 gets attracted by the edge field of the nanowire 10 at the free end 11 of the nanowire 10, and gets annihilated. Thus, the edge field at the free end 11 of the nanowire 10 can be said to prevent formation of a second domain wall in the nanowire 10. The DW 90 at the right or second edge 22 of the conductive strip 20 becomes stable due to the absence of magentostatic interaction.

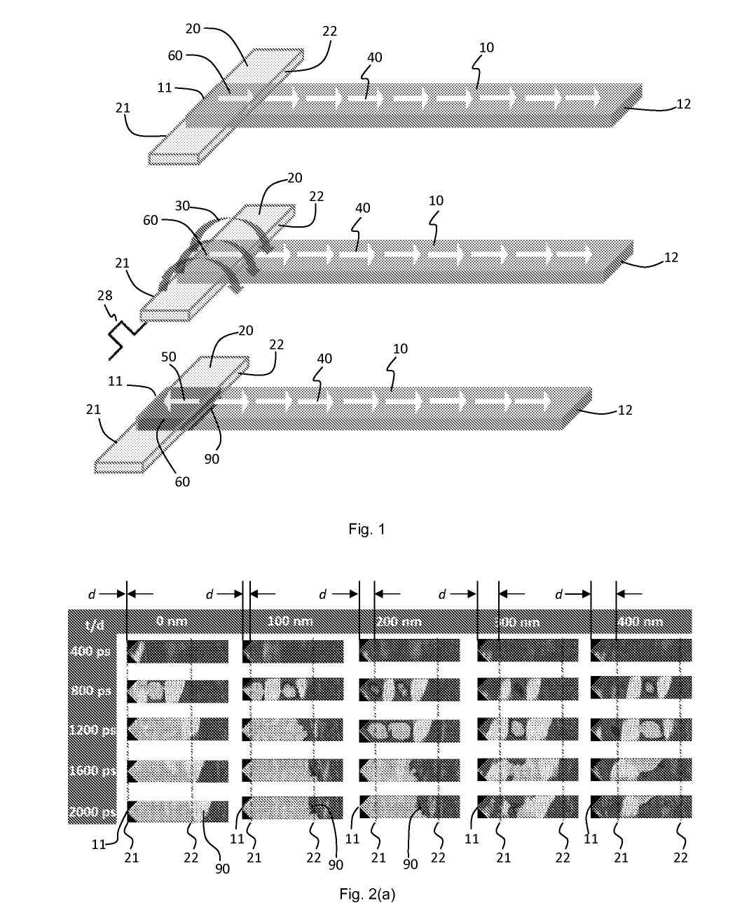

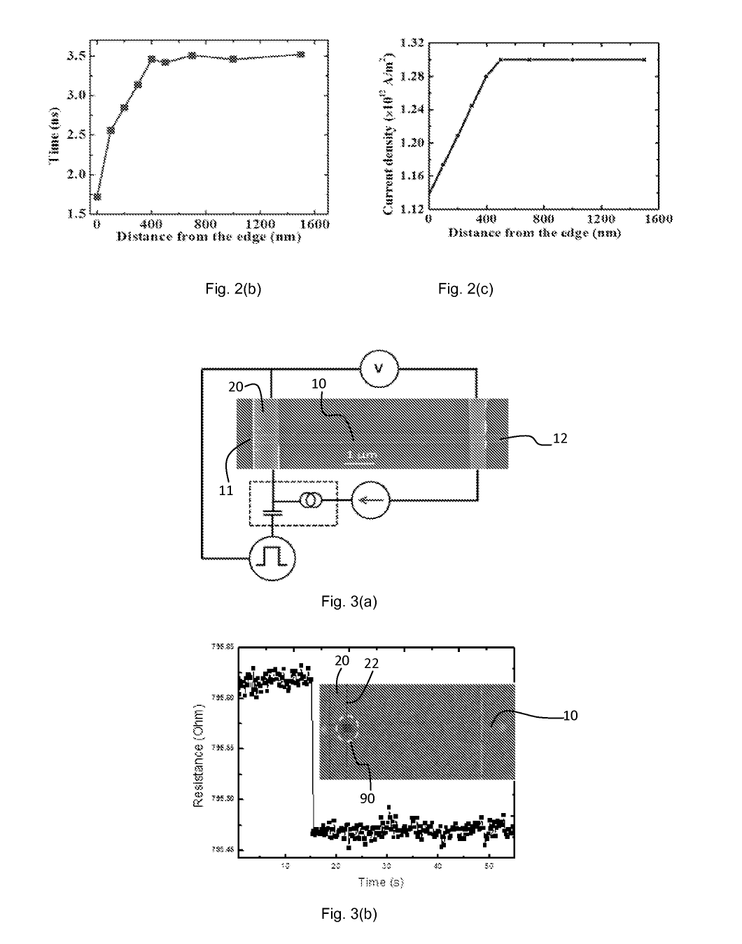

In the experiments conducted, position of the conductive strip 20 relative to the free end 11 of the nanowire 10 was varied while keeping pulse duration and current density constant. FIG. 2 (a) shows magnetization configurations of the nanowire 10 at different stages of the simulations. To generate the Oersted field 30, a pulse current was applied to the conductive strip 20 with rise and fall times taken as 300 ps (picoseconds) and the pulse width considered as 1 ns (nanosecond). The current density was 1×10¹² A/m². The total simulation time was 2 ns or 2000 ps, which was twice the length of the injection or formation pulse duration.

Initially, the conductive strip 20 overlapped with the edge or free end 11 of the nanowire 10, i.e., a distance d between the first edge 21 of the conductive strip 20 and the nanowire edge or free end 11 of the nanowire was zero, i.e., d=0 nm. Nucleation of the DWs in the nanowire 10 started only at 800 ps. Interestingly, a DW formed in the nanowire 10 near the nanowire edge 11 or free end 11 of the nanowire 10 was annihilated (not shown), and a stable single DW 90 was formed in the nanowire 10 at 1200 ps. The DW 90 also moved towards the second end 12 of the nanowire 10, i.e., away from or out of the conductive strip 20 after its formation.

When the conductive strip 20 was placed 100 nm away from the edge or free end 11 of the nanowire 10, i.e., d=100 nm, the spin evolution at 800 ps showed that DW nucleation is slower compared to the previous case where d=0. A single DW 90 was formed successfully, however this was formed only beneath the conductive strip 20 and did not move towards the second end 12 of the nanowire 10 even at 2 ns (2000 ps).

In the case of d=200 nm, although the single DW 90 was successfully nucleated, it remained within the conductive strip 20 and did not move towards the second end 12 of the nanowire 10.

For d=300 nm & 400 nm, the Oersted field 30 completely failed to nucleate DWs.

From the above observations, it is clear that the nanowire edge stray field does play a key role in DWs generation. However, its effect decreases as the conductive strip 20 is placed away from free end 11 of the nanowire 10. FIGS. 2(b) and 2(c) show the plots defining the maximum distance for which the edge stray field is effective and/or can be compensated for by increasing the pulse duration or the current density, respectively. It is clear from the graphs that for d>500 nm, the effect of the stray field is negligible for the nanowire 10 having the particular dimensions and properties as used in the experiments.

Micromagnetic simulations were performed to optimize the threshold distance d of the conductive strip 20 from the free end 11 of the nanowire 10 relative to the width of the nanowire 10 when the current density was fixed at J=1×10¹² A/m². The pulse width was 1 ns and rise and fall times were chosen as 300 ps. A gold conductive strip 20 having the same dimensions as that used in the experiments described above was used.

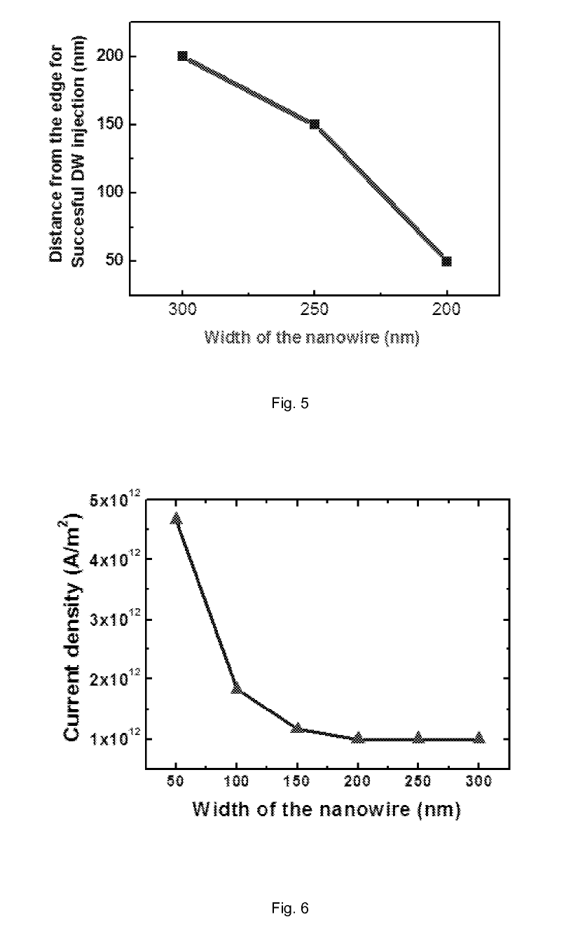

The threshold distance d was plotted against the nanowire width as shown in FIG. 5. It was observed that when the width of the nanowire 10 was reduced, the conductive strip 20 had to be placed closer to the free end 11 of the nanowire 10 (i.e. a smaller value for d) for successful DW injection. Thus, the distance d is reduced when the width of the nanowire is reduced. However, when the width of the nanowire 10 was less than 200 nm, the DW injection was not successful even when the conductive strip 20 completely overlapped with the free end 11 of the nanowire, i.e., when d=0 nm at the current density of J=1×10¹² A/m².

The results can be understood from the fact that when the nanowire width is reduced, its shape anisotropy increases. Thus, a higher energy is needed to nucleate the DW. When the conductive strip 20 is placed close to the free end 11 of the nanowire 10, the energy from the stray field assists the current to separate the DWs that are nucleated (for nanowire width >200 nm). When the nanowire width <200 nm, the edge stray field is not enough to assist the DWs separation at J=1×10¹² A/m². A higher current is therefore required for successful DW nucleation when the width of the nanowire 10 is less than 200 nm even though d=0 nm. We can also understand that it would be best to completely overlap the conductive strip (d=0) with the free end 11 of the nanowire 10 (maximum stray field assistance) because the current density required for DW injection is minimum in this case (for low power operation).

The current density required for the successful single DW injection is optimized as a function of the nanowire width when d=0 nm. The results are plotted as shown in FIG. 6. This reveals that the current density drops asymptotically when the width of the nanowire 10 is reduced. The reason behind this trend is again due to the shape anisotropy of the nanowire 10. The higher the width of the nanowire, the lower the shape anisotropy which means a lower current is sufficient for DW nucleation. It is to be noted that all these results give a qualitative trend without being restricted to quantitative values. Different values may be obtained experimentally by changing the material or the thickness of the nanowire 10.

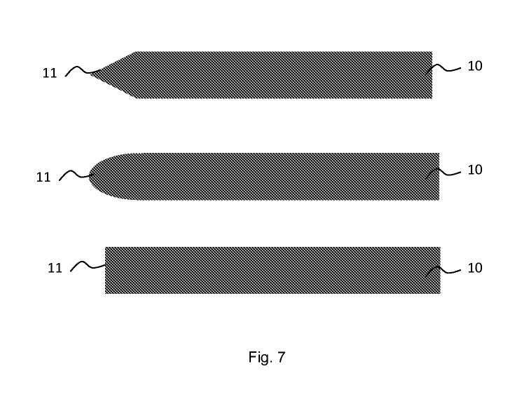

Varying the shape of the free end 11 of the nanowire 10 as shown in FIG. 7 (for example, triangular/pointed, rounded or straight) did not show much effect on the current density required and maximum d for DW injection. However, a pointed free end 11 is preferred in order to avoid additional DW nucleation from the free end 11 into the nanowire 10 during device operation.

The above-described experiments and simulations thus reveal the importance of nanowire edge field in deterministic DW generation. The typical time for DW generation is also found to be lower when the DW is generated at the edge or end 11 of the nanowire 10. Moreover, the critical current density for DW generation is lower when the conductive strip 20 is closer to the edge or end 11 of the nanowire, as the DW generation does not need to overcome mutual attraction between two DWs.

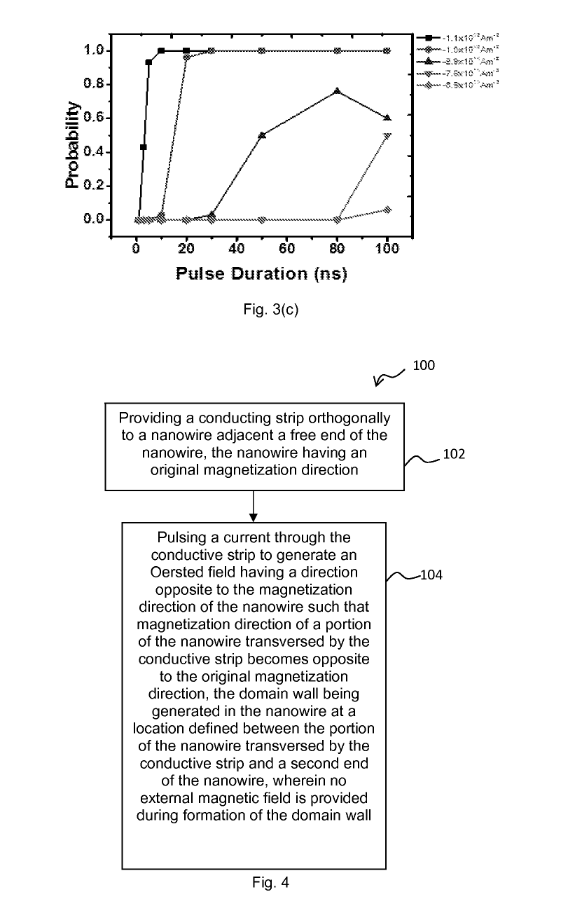

Shown in FIG. 3(a) is a scanning electron microscopy image of a nanowire 10 with a transverse conductive strip 20 for DW injection or formation overlapped with an electrical circuit to pass a current pulse and measure the magnetoresistance along the nanowire 10. Fabrication of the nanowire 10 was done by depositing Cr(3 nm)/NiFe(10 nm)/Cr(3 nm) on a silicon substrate using thermal evaporation. The nanowire was patterned by using electron beam lithography and Ar ion beam etching. For the injection or formation of the conductive strip 20 and contact pads, a second step of lithography was done using positive resist. Ta(5 nm)/Au(30 nm) was then deposited by dc magnetron sputtering, followed by lift-off process. The injection or formation or current pulse was done using a current density of 1.1×10¹² A/m² and pulse width of 10 ns. The scanning electron microscopy image clearly shows the transverse conductive strip 20 overlapped close to the nanowire edge or free end 11 of the nanowire 10 for DW injection or formation into the nanowire 10.

As can be seen in FIG. 3(b), the DW generation can be seen as a drop in the resistance of the nanowire due to the DW magnetoresistance [5]. Inset shows a corresponding magnetic force microscopy image of the nanowire 10 after DW injection or formation. It clearly shows a single DW (dark spot) 90 generated at the edge 22 of the conductive strip 20.

The probability of the DW injection or formation was further experimentally investigated as a function of current density and pulse duration. The DW generation of the above described method 100 was repeated 50 times, each at different current density and pulse duration to map the probability of successful injection or formation. FIG. 3(c) shows the probability of DW injection or formation for various current densities as a function of pulse duration. The threshold current density is found to be 1.1×10¹² A/m², that is, a current density of at least 1.1×10¹² A/m² is required for domain wall formation. From the probability plot, it is clear that the DW injection or formation into the nanowire 10 becomes deterministic at a current density of 1.1×10¹² A/m² with a 10 ns pulse width. This is the first demonstration of deterministic DW injection or formation into a nanowire in the absence of an external magnetic field.

Whilst there has been described in the foregoing description exemplary embodiments of the present invention, it will be understood by those skilled in the technology concerned that many variations in details of design, construction and/or operation may be made without departing from the present invention.

### REFERENCES

[1] S. S. P. Parkin, M. Hayashi and L. Thomas, Science, 320, 190 (2008).
[2] A. Pushp, T. Phung, C. Rettner, B. P. Hughes, S. H. Yang, L. Thomas and S. Parkin, Nature Phys. 9, 505 (2013).
[3] L. Thomas, M. Hayashi, R. Moriya, C. Rettner, C. and S. S. P. Parkin, Nat. Commun. 3, 810 (2012).
[4] A. Annunziata et al., Proc. IEEE International Electron Devices 2011, 539
[5] M. Hayashi, L. Thomas, C. Rettner, R. Moriya, and S. S. P. Parkin, Nature Phys. 3, 21 (2007).

1. A method of forming a domain wall in a nanowire, the method comprising the steps of:
a) providing a conductive strip orthogonally to a nanowire adjacent a free end of the nanowire, the nanowire having an original magnetization direction;
b) pulsing a current through the conductive strip to generate an Oersted field having a direction opposite to the original magnetization direction such that magnetization direction of a portion of the nanowire transversed by the conductive strip becomes opposite to the original magnetization direction, the domain wall being generated in the nanowire at a location defined between the portion of the nanowire transversed by the conductive strip and a second end of the nanowire, wherein no external magnetic field is provided during formation of the domain wall.

2. The method of claim 1, wherein in step a), a first edge of the conductive strip is at a distance from the free end of the nanowire that is sufficient for an edge field at the free end of the nanowire to prevent formation of a further domain wall in the nanowire adjacent the free end of the nanowire.

3. The method of claim 2, wherein a width of the nanowire is not less than 200 nm.

4. The method of claim 3, wherein the distance ranges from 0 nm to 500 nm.

5. The method of claim 4, wherein the distance is reduced when the width of the nanowire is reduced.

6. The method of claim 1, wherein the current has a current density of at least 1.1×10¹² A/m².

7. The method of claim 1, wherein the current has a pulse width of 10 ns.
